(19) United States
(12) Patent Application Publication
(10) Pub. No.: US 2009/0282185 A1
(43) Pub. Date: Nov. 12, 2009

(54) FLASH MEMORY DEVICE AND A METHOD FOR USING THE SAME

(75) Inventor: Geert R. J. Van Cauwenbergh, Wolvertem (BE)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: NXP B.V., Eindhoven (NL)

(21) Appl. No.: 12/306,911

(22) PCT Filed: Jun. 19, 2007
(86) PCT No.: PCT/IB07/52350

§ 371 Date: Dec. 29, 2008

(30) Foreign Application Priority Data
Jun. 30, 2006 (EP) 06116478.6

(51) Int. Cl. G06F 12/02; G06F 12/00; G11C 11/34

(52) U.S. Cl. 711/103; 365/185.33; 711/E12.001; 711/E12.008

(57) ABSTRACT

A flash memory device is presented. The device includes a flash memory, which has a temporary storage portion, a main storage portion and a controller. The temporary storage portion is provided for buffering data and addresses. The buffered addresses are indicative of the destination of the buffered data in the main storage portion. The controller is configured for selectively accessing the main storage portion or the temporary storage portion or a combination thereof for receiving and/or outputting the data from the memory. The controller is further configured for enabling communication of data between the two portions. Because non-volatile flash memory is used for the temporary storage, no other memory components are needed and, in case of an unexpected power failure, the data in the temporary area is not lost.

The invention relates to a flash memory device and a method for using the same.

Flash memories are commonly used memories. A flash memory is a non-volatile memory that means the memory does not need power to preserve data stored in it. A flash memory comprises blocks; each block is typically of size 128 Kbytes. A block comprises pages; each page is typically of size 2 Kbytes. A flash memory can be programmed or read a page at a time—just like other memories—in a random access manner, however erasing must be done a block at a time. Consequently for making even a small alteration in the contents of a block, the entire block requires to be rewritten which causes a time overhead. With each new generation of flash memory the block size tends to increase, and with the increase in the block size the overhead grows. Furthermore, flash memories wear-out i.e. each block of a flash memory can only be erased and rewritten for a predetermined number of times before the reliability of the block starts decreasing. Another general problem faced by a memory is the speed mismatch amongst the microprocessor and the memory. This mismatch of speed results in stalling the microprocessor. This problem is also faced by flash memories.

Therefore, it is desirable to provide a memory system that has all the advantages of non-volatile memories and does not have above and other limitations.

To this end, the invention provides a device comprising: a flash memory, said flash memory having a temporary storage portion and a main storage portion and a controller for selectively accessing the main storage portion or the temporary storage portion or a combination thereof, the controller being configured for buffering data and an addresses in the temporary storage portion, wherein the addresses indicates the destination of the buffered data in the main storage portion.

This aspect of the invention provides a non-volatile temporary storage portion for the purpose of temporarily storing of data. The temporary storage portion is substantially smaller than the main storage portion, typically the main storage portion is 512 Mbytes or more and the temporary storage portion may be of the order of 1 Mbytes. The data is stored in the temporary storage portion sequentially regardless of the final destination of the data in the main storage portion. Therefore, writing in the temporary storage portion requires less time overhead than writing to the main storage portion. Further providing a temporary storage portion within the flash memory provides a faster flash memory as compared to the flash memories without a temporary storage portion. Data that is to be written in the main storage portion may be buffered in the temporary storage portion along with corresponding address of the data. The buffered address may be a physical address, which directly indicates a destination of the buffered data in the main storage portion. Alternatively the buffered addresses may be a logical address, which indirectly indicates the destination of the buffered data in the main storage portion. The logical addresses may be mapped on to physical addresses by a lookup table. According to the logical or physical addresses data may be communicated between the temporary storage portion and the main storage portion. Usually, the controller receives an address of a data-packet and a number of data-packets that will follow the data-packet, accordingly for each following data-packet an address is generated by adding ‘one’ to the address of preceding data-packet by the controller. The data-packets according to their addresses are then stored sequentially in the temporary storage portion or in the main storage portion. However, according to an aspect the controller may receive a plurality of addresses each address corresponding to a data-packet, in this case the data-packets are still stored sequentially in the temporary storage portion, but may not necessarily required to be stored sequentially in the main storage portion. The buffered data can be transferred to the main storage portion when the temporary storage portion is full or the accessing is terminated or on a request received by the controller to do so. The data packets are transferred from the temporary storage portion to the main storage portion in order of the destination address in main storage, this way if different data packets in the temporary storage portion are to be stored in the same block of the main storage portion it suffices to erase that block only once. If this data were written directly to the main storage portion after each request that block had to be erased a plurality of times. Hence the data shuffling required for writing data in main storage portion reduces substantially resulting in an increased life time and the speed of the memory.

It is noted U.S. Pat. No. 6,026,027 discloses a flash memory having a cache. This memory uses a Static Random Access Memory (SRAM) as a cache. In the device according to the present invention a portion of the flash memory itself is used to buffer data for storage in another portion of the flash memory. At first sight this measure would seem to aggravate wear of the flash memory as the buffered data is written twice therein. It is therefore surprising that in this way wear of the memory can be reduced and the total average writing speed of the memory can be increased.

According to one aspect of the device, the controller may be programmed for directly storing data in the main storage portion. Storing data directly in main storage portion may be advantageous when a data stream which is required to be stored having at least a predetermined number of data-packets. The predetermined number corresponds, for example, to a number of data-packets that can be stored in a predetermined number of locations. According one example the predetermined number of locations may be 4 pages of the main storage portion. The number “4 pages” is an exemplary number, which may vary according to the file system used for accessing the memory or the type of files used for storing the memory or according to the application for which the memory is being designed. Further directly storing of data in the main storage portion may be advantageous when a data stream is required to be stored in mutually consecutive locations of the main storage portion, said data stream having a number of data-packets and the number is more than or equal to the predetermined number.

According to a further embodiment, the controller is configured for receiving data for, and/or outputting data from, the flash memory. According to this aspect the controller checks if data desired by a read operation is present in the temporary storage portion. Accordingly the controller outputs the desired data in a read operation from the temporary storage portion or from the main storage portion. Further this aspect allows the controller to receive data for storing it into the memory, and to store the data in the main storage portion of the memory or to store the data sequentially in the temporary storage portion of the memory.

According to an embodiment of the invention, the controller is configured for enabling an adaptive data communication between the temporary storage portion and the main storage portion while minimising shuffling of data already stored in the main storage portion. The controller may be programmed to adaptively change the mapping of the addresses for ensuring a minimal shuffling of data that is already stored in the main storage portion, while communicating data between the main storage portion and the temporary storage portion. Such programming allows a least number of erase operations of the main storage portion of the memory and hence the memory wear is minimized. According to one example of adaptively changing the mapping, the controller may identify a least used block in the main storage portion and use the identified block for storing contents of a block of main storage portion after altering it according to the temporary storage portion of the memory. According to another aspect the controller may be configured to determine whether the temporary storage portion comprises a plurality of data items having a same destination in the main storage portion, and if such a plurality is found then selecting the newest data-item of said plurality for storing in the main storage portion. This aspect avoids unnecessary erase operations and therefore minimizes shuffling of data already stored in the main storage portion and improves life time of the memory.

According to another embodiment the invention provides a method for storing data in a flash memory device comprising an indirect storage mode with the steps of: receiving data; buffering data, as well as an address in a temporary storage portion in said flash memory device, said address being indicative for a destination of the buffered data in the main storage portion, and; transferring the data in the main storage portion at the destination indicated by the address. This aspect of the method allows a buffering of data in the temporary storage portion of the flash memory.

According to an embodiment the method further comprises a direct storage mode with the steps of: receiving a data stream, and storing directly the data stream in the main storage portion, the direct storage mode being executed if the data stream has at least a predetermined number of data-packets for storage in a plurality of consecutive locations of the main storage portion, and the indirect mode being executed otherwise. The direct storage mode is executed if the data stream has at least a predetermined number of data-packets for storage in a block of the main storage portion. This aspect of the invention prevents buffering of the data stream, therewith allowing an even more efficient use of the memory resource, if the data stream that is to be stored is long enough and extends over a plurality of sectors.

The predetermined number corresponds, for example, to a number of data-packets that can be stored in a predetermined number of locations. According one example the predetermined number of locations may be 4 pages of the main storage portion. The number “4 pages” is an exemplary number, which may vary according to the file system used for accessing the memory or the type of files used for storing the memory or according to the application for which the memory is being designed.

According to an embodiment the method further provides the step of: adaptively communicating data between the temporary storage portion and the main storage portion, while minimizing shuffling of data already stored in the main storage portion. According to this aspect for communicating adaptively data between the two portions, mapping of the addresses may be adaptively changed. This aspect of the method achieves an efficient communication between the two portions and increases the life time of the memory.

According to another embodiment, the method further comprises the step of: determining whether the temporary storage portion comprises a plurality of data-packets having a same destination in the main storage portion, and; if such a plurality is found selecting the newest data-item of said plurality for storing in the main storage portion. This aspect of the method achieves eliminating unnecessary iterations of erasing of main storage portion of the memory when the data has already been updated in the temporary storage portion of the memory.

According to a further embodiment, the method provides retrieving of data from a flash memory device comprising the steps of: receiving one or more addresses being indicative of locations from where data is to be retrieved, and; supplying data from a temporary storage portion if the addresses are present in the temporary storage portion of flash memory device and else supplying data from a main storage portion of the flash memory device. This aspect achieves reading from the flash memory. For the purpose of a foolproof execution of a read operation, when some part of the content of the memory is written in the temporary storage portion and some part of the content of the memory is in main storage portion of the memory, it is required to check whether the data is present in temporary storage portion, of the memory. Accordingly the data is obtained from temporary storage portion if it is present in it; else the data is obtained from the main storage portion of the memory.

These and further aspects and advantages of the method and the device according to the invention will be now discussed in more detail hereinafter with reference to enclosed drawings, therein;

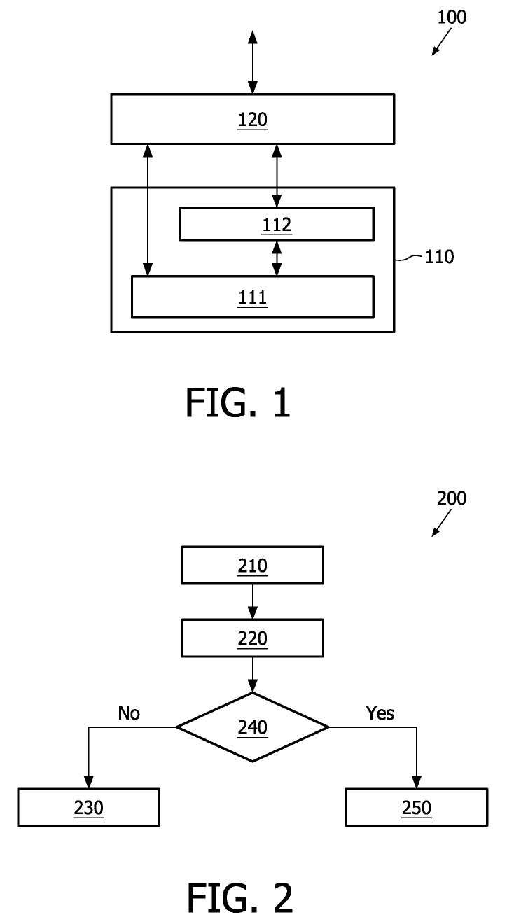

FIG. 1 shows a flash memory device in accordance with the invention;

FIG. 2 shows a flow diagram in accordance with a first aspect of the method of the invention;

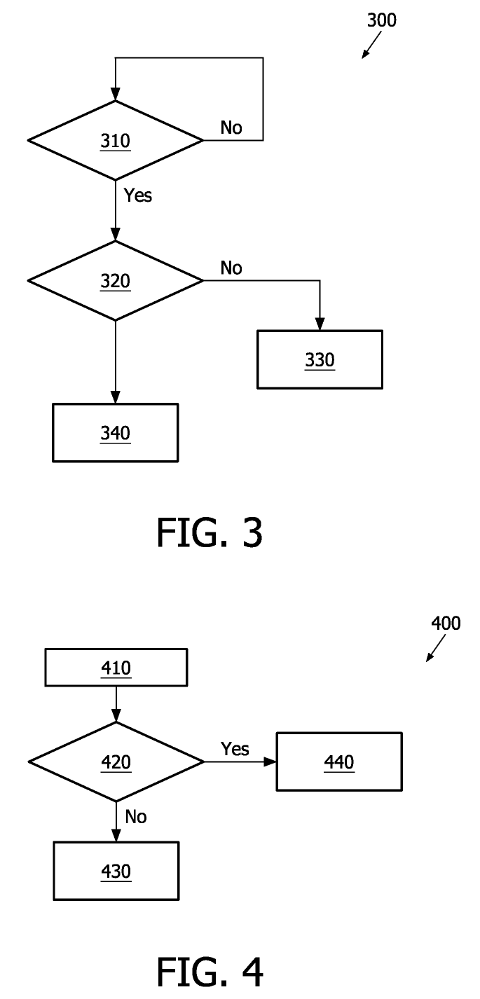

FIG. 3 shows a flow diagram in accordance with a second aspect of the method of the invention;

FIG. 4 shows a flow diagram in accordance with a third aspect of the method of the invention, and;

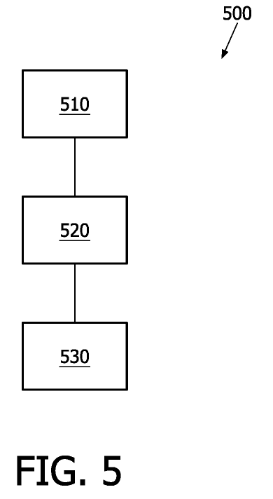

FIG. 5 shows a flow diagram in accordance with a fourth aspect of the method of the invention.

FIG. 1 shows a flash memory 100 device in accordance with the invention. The device comprises a flash memory 110 having a temporary storage portion 112, a main storage portion 111 and a controller 120. The temporary storage portion 112 is provided for buffering data and addresses. The buffered addresses are indicative of the destination of the buffered data in the main storage portion 111. The controller 120 is configured for selectively accessing the main storage portion 111 or the temporary storage portion 112 or a combination thereof for receiving and/or outputting the data into/from the memory 110. The controller 120 is further configured for enabling communication of data between the two portions 111, 112.

FIG. 2 shows a flow diagram 200 in accordance with an aspect of the method of the invention. The figure depicts storing operation in the memory 110. The controller 120 receives data and in the step 220 it determines size of data that is to be written. In the step 240 a decision to store 230 data in temporary storage portion 112 or to store 250 main storage portion 111 is made. If the data size is more than the size that would fit in 4 pages of the main storage portion 111, then the data is directly stored 250 in main storage portion 111 else the data is stored in temporary storage portion 112. The number “4 pages” is an exemplary number, which may vary according to the file system used for accessing the memory or the type of files used for storing the memory. Steps 210, 220, 240 and 250 together represent a direct storage mode. Steps 210, 220, 240 and 230 represent an indirect storage mode.

FIG. 3 shows another flow diagram 300 in accordance with a second aspect of the method of the invention. The Figure depicts transfer (communication) operation of data from temporary storage portion 112 to main storage portion 111. In step 310 it is determined whether a transfer of data is required. If a transfer is required then in step 320 it is determined for each address stored in the temporary storage portion 112 whether there is more than one data items having it as the destination in the main storage portion. If this is the case then only the latest amongst the plurality of data items is transferred to said address. Otherwise the only data element is written to said address. The data packets are transferred from the temporary storage portion to the main storage portion in order of the destination address in main storage, this way if different data packets in the temporary storage portion are to be stored in the same block of the main storage portion it suffices to erase that block only once. If this data were written directly to the main storage portion after each request that block had to be erased a plurality of times. Hence the data shuffling required for writing data in main storage portion reduces substantially resulting in an increased life time and the speed of the memory. The step 310 may determine if a transfer is required based on the case if the temporary storage portion is full or the accessing of the memory is terminated or on a request received by the controller to do so.

FIG. 4 shows another flow diagram 400 in accordance with a third aspect of the method of the invention. A read operation is depicted in the Figure. In step 410 a request for executing a read operation is received along with at least one address of a location from where data item is to be read is received. In step 420 it is determined whether the address exists in the temporary storage portion 112. If this is the case then the data corresponding to the address is retrieved 430 from the temporary storage portion 112 else the data is retrieved 440 from the main storage portion 111.

The temporary storage portion 112 of the memory is realized using a non-volatile memory hence it has all the advantages of the non-volatile memory i.e., the memory is cheap and in case of unexpected power failure, the data is not lost, further no other memory components are needed. The temporary storage portion 112 is (typically 1 Mbyte or less) substantially smaller than the main storage portion 111 (typically in hundreds of Mbytes or more). Therefore, writing in the temporary storage portion 112 requires less time overhead then writing to the main storage portion. Data that is to be written in the main storage portion 111 may be buffered in the temporary storage portion 112 along with the corresponding address of the data. The buffered addresses may be a physical address, which directly indicate a destination of the buffered data in the main storage portion 111. Alternatively, the buffered addresses may be a logical address which, indirectly indicate the destination of the buffered data in the main storage portion 111. The logical addresses may be mapped on to physical addresses by a look-up table. According to the logical or physical addresses data may be communicated to between the temporary storage portion 112 and main storage portion 111.

The controller 120 may be programmed to adaptively change the mapping of the addresses for ensuring a minimal shuffling of data that already stored in the main storage portion 111. Such programming allows a least number of erase operations of the main storage portion 111 of the memory 110 and hence the memory wear is minimized. According to one example of adaptively changing the mapping, the controller 120 may identify a least used block in the main storage portion 111 and use the identified block for storing contents of a block of main storage portion 111 after altering it according to the temporary storage portion 112 of the memory 110. According to another aspect, the controller may be configured to determine whether the temporary storage portion 112 comprises a plurality of data items having a same destination in the main storage portion 111, and if such a plurality is found then selecting the newest data-item of said plurality for storing in the main storage portion 111. This aspect avoids unnecessary erase operations and therefore minimizes shuffling of data already stored in the main storage portion 111 and improves life time of the memory 110.

According to one aspect of the device, the controller 120 may be programmed for directly storing data in the main storage portion 111. Storing data directly in main storage portion may be advantageous when a data stream which is required to be stored having at least a predetermined number of data-packets. The predetermined number corresponds, for example, to a number of data-packets that can be stored in a predetermined number of locations, According one example the predetermined number of locations may be 4 pages of the main storage portion 111. The number “4 pages” is an exemplary number may vary according to the file system used for accessing the memory or the type of files used for storing the memory. Further directly storing of data in the main storage portion may be advantageous when a data stream is required to be stored in mutually consecutive locations of the main storage portion 111, said data stream having a number of data-packets and the number is more than or equal to the predetermined number.

According to a further embodiment of the controller 120 is configured for receiving data for, and/or outputting data from the flash memory. According to this aspect of the controller 120 checks if data desired by a read operation is present in the temporary storage portion 112. Accordingly the controller 120 outputs the desired data in a read operation from temporary storage portion 112 or from main storage portion 111. Further the direct storing mode allows the controller 120 to receive data for storing it into the memory 110, and store the data in the main storage portion 111 of the memory 110 or store the data sequentially in the temporary storage portion of the memory.

According to another aspect the invention provides a method for storing data in a flash memory device 100 comprising an indirect storage mode (depicted in FIG. 5) with the steps of: receiving data 510; buffering data 520, as well as an address in a temporary storage portion in said flash memory device, said address being indicative for a destination of the buffered data in the main storage portion, transferring the data 530 in the main storage portion at the destination indicated by the address.

This aspect of the invention may be understood as the step 230 followed by step 320 and the step 330 or the step 340. However for clarity FIG. 5 shows the steps according to this aspect of the method. The step 510 may include steps 210, 220 and 240 in which the data is received and it is determined if the data should be stored in the main storage portion 111 or in the temporary storage portion 112. The step 520 includes the step 230 in which the data is stored in the temporary storage portion 112. The step 530 includes the step 320 and 330 or 340 in which the data is transferred to main storage portion 111. This aspect of the method allows a buffering of data in the temporary storage portion of the flash memory.

The order in the described embodiments of the method and device of the current discussion is not mandatory, and is illustrative only. The scope of the discussion is not limited to the described embodiments. A person skilled in the art may change the order of steps or perform steps concurrently using threading models, multi-processor systems or multiple processes without departing from the concept as intended by the current discussion. Any such embodiment will fall under the scope of the discussion and is a subject matter of protection. It should be noted that the above-mentioned embodiments illustrate rather than limit the method and device, and that those skilled in the art will be able to design many alternative embodiments without departing from the scope of the appended claims. In the claims, any reference signs placed between parentheses shall not be construed as limiting the claim. The word “comprising” does not exclude the presence of elements or steps other than those listed in a claim. The word “a” or “an” preceding an element does not exclude the presence of a plurality of such elements. The method and device can be implemented by means of hardware comprising several distinct elements, and by means of a suitably programmed computer. In the device claims enumerating several means, several of these means can be embodied by one and the same item of computer readable software or hardware. The mere fact that certain measures are recited in mutually different dependent claims does not indicate that a combination of these measures cannot be used to advantage.

1. A device comprising: a flash memory, said flash memory having a temporary storage portion and a main storage portion and a controller for selectively accessing the main storage portion or the temporary storage portion or a combination thereof, the controller being configured for buffering data and an addresses in the temporary storage portion, wherein the addresses indicates the destination of the buffered data in the main storage portion.

2. The device according to claim 1 wherein said controller is further configured for directly storing data in the main storage portion.

3. The device according to claim 1 wherein said controller is further configured for receiving data for, and/or outputting data from, the flash memory.

4. The device according to claim 1 wherein said controller is further configured for enabling an adaptive data communication between the temporary storage portion and the main storage portion, while minimizing shuffling of data already stored in the main storage portion.

5. A method for storing data in a flash memory device comprising an indirect storage mode with the steps of:
receiving data;
buffering data, as well as an address in a temporary storage portion in said flash memory device, said address being indicative for a destination of the buffered data in the main storage portion, and;
transferring the data to the main storage portion at the destination indicated by the address.

6. A method according to claim 5 further comprising a direct storage mode with the steps of:
receiving a data stream, and;
storing directly the data stream in the main storage portion, the direct storage mode being executed if the data stream has at least a predetermined number of data-packets for storage in a plurality of consecutive locations of the main storage portion, and the indirect mode being executed otherwise.

7. The method according to claim 6 wherein said predetermined number corresponds to a number of data-packets that can be stored at least in 4 pages of the main storage portion.

8. The method according to claim 5 further comprising the step of:
adaptively communicating data between the temporary storage portion and the main storage portion, while minimizing shuffling of data already stored in the main storage portion.

9. The method according to claim 5 further comprising the step of;
determining whether the temporary storage portion comprises a plurality of data items having a same destination in the main storage portion, and if such a plurality is found then selecting the newest data-item of said plurality for storage in the main storage portion.

10. A method for retrieving data from a flash memory device comprising the steps of:
receiving at least one address being indicative of a location from where data is to be retrieved, and;
supplying data from a temporary storage portion if the at least one address is present in the temporary storage portion of the flash memory device and else supplying data from a location in the main storage portion of the flash memory device, the location being indicated by the at least one address.
